(19) United States
(12) Patent Application Publication
(10) Pub. No.: US 2015/0381168 A1
(43) Pub. Date: Dec. 31, 2015

(54) HIGH FREQUENCY SWITCHING CIRCUIT

(71) Applicant: KABUSHIKI KAISHA TOSHIBA, Tokyo (JP)

(72) Inventor: Kouji UEJIMA, Kawasaki Kanagawa (JP)

(21) Appl. No.: 14/634,004

(22) Filed: Feb. 27, 2015

(30) Foreign Application Priority Data
Jun. 25, 2014 (JP) 2014-130421

(51) Int. Cl. H03K 17/687; H04B 1/401; H04B 1/44

(52) U.S. Cl. CPC H03K 17/687; H04B 1/44; H04B 1/401

(57) ABSTRACT

A high frequency switching circuit for a first high frequency signal that is input through a first terminal and a second high frequency signal that is input through a second terminal includes a first transmission line connecting a first transistor to the first terminal. The first transmission line has a line length that is an integer multiple of a quarter wavelength of the first high frequency signal. The first transistor is connected between the first terminal and the second terminal and changes conduction state according to a first control signal. A second transmission line connects a second transistor to a third terminal. The second transistor is connected between the second terminal and a third terminal and changes conduction state according to a second control signal. The second transmission line has a line length that is an integer multiple of a quarter wavelength of the second high frequency signal.

### CROSS-REFERENCE TO RELATED APPLICATION

This application is based upon and claims the benefit of priority from Japanese Patent Application No. 2014-130421, filed Jun. 25, 2014, the entire contents of which are incorporated herein by reference.

### FIELD

Embodiments described herein relate generally to a high frequency switching circuit.

### BACKGROUND

A high frequency switching circuit including a plurality of transistors is an important component of wireless communication systems used in mobile communications, local area networks (LAN), and the like. These high frequency switch circuits are used in communications devices such as, for example, mobile phones, wireless infrastructure equipment, satellite communication equipment, cable TV equipment, and other networked and networking devices.

A high frequency switching circuit includes a through-transistor, provided on a high frequency terminal side, and a shunt transistor, provided on a ground potential side. There is a problem that if the leakage of a high frequency signal occurs, then signal pass characteristics, isolation characteristics, or the like are degraded in the high frequency switching circuit.

### DESCRIPTION OF THE DRAWINGS

FIG. 1 is a circuit diagram illustrating a high frequency switching circuit according to a first embodiment.

FIG. 2 is a circuit diagram illustrating a high frequency switching circuit according to a comparison example.

FIG. 3 is an equivalent circuit diagram of the high frequency switching circuit according to the first embodiment when a high frequency signal is being output to an antenna terminal via a transmitting terminal.

FIG. 4 is an equivalent circuit diagram of the high frequency switching circuit of the comparison example when a high frequency signal is being output to an antenna terminal via a transmitting terminal.

FIG. 5 is an equivalent circuit diagram of the high frequency switching circuit according to the first embodiment when the high frequency signal is being output to a receiving terminal via the antenna terminal.

FIG. 6 is an equivalent circuit diagram of the high frequency switching circuit of the comparison example when a high frequency signal is being output to a receiving terminal via the antenna terminal.

FIG. 7 is a diagram of frequency versus insertion loss of the high frequency switching circuit according to the first embodiment.

FIG. 8 is a circuit diagram illustrating a high frequency switching circuit according to a first modification example.

FIG. 9 is a circuit diagram illustrating a high frequency switching circuit according to a second embodiment.

### DETAILED DESCRIPTION

Exemplary embodiments describe a high frequency switching circuit which may reduce the leakage of a high frequency signal.

In general, according to one embodiment, a high frequency switching circuit for high frequency signals including a first high frequency signal that is input through a first terminal and a second high frequency signal that is input through a second terminal, includes a first transmission line connecting a first end of a first transistor to the first terminal (e.g., a transmitter terminal). The first transmission line has a line length that is an integer multiple of a quarter of a wavelength of the first high frequency signal. A second end of the first transistor is connected to the second terminal (e.g., an antenna terminal). A control electrode (gate) of the first transistor is connected to a first control input terminal at which a first control signal is receivable. A second transmission line connects a first end of a second transistor and a third terminal (e.g., a receiver terminal). The second transmission line has a line length that is an integer multiple of a quarter of a wavelength of the second high frequency signal. A second end of the second transistor is connected to the second terminal. A control electrode (gate) of the second transistor is connected to a second control input terminal at which a second control signal is receivable.

Hereinafter, example embodiments will be described with reference to the drawings.

### First Embodiment

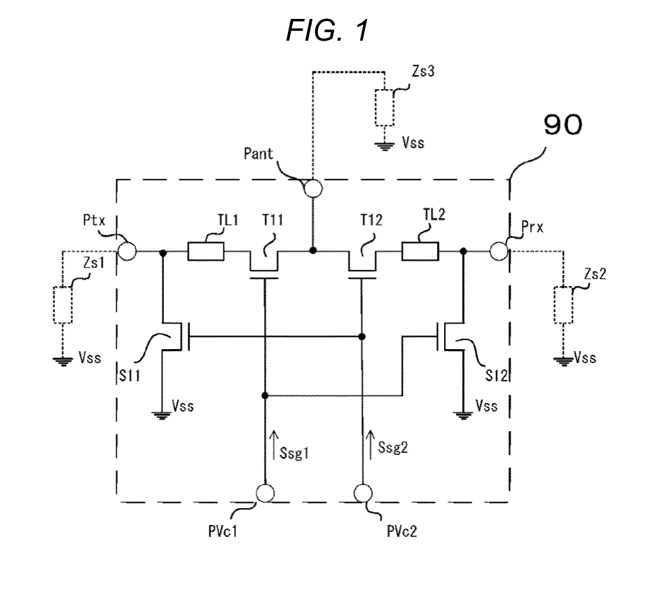

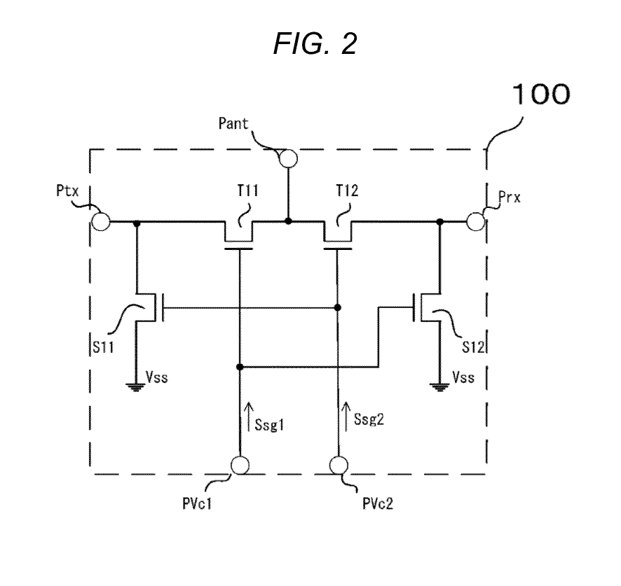

FIG. 1 is a circuit diagram illustrating the high frequency switching circuit according to a first embodiment. FIG. 2 is a circuit diagram illustrating a high frequency switching circuit of a comparative example. In the first embodiment, transmission lines which are each a quarter of the wavelength of a high frequency signal in length are between a transmitting terminal and a first through-transistor, and also between a second through-transistor and a receiving terminal and thereby the leakage of the high frequency signal is reduced.

As illustrated in FIG. 1, a high frequency switching circuit 90 includes a shunt transistor S11, a shunt transistor S12, a through-transistor T11, a through-transistor T12, a transmission line TL1, a transmission line TL2, a terminal Pant, a terminal Prx, a terminal Ptx, a terminal PVc1, and a terminal PVc2.

The high frequency switching circuit 90 is a single pole double throw (SPDT) switch. The high frequency switching circuit 90 can be used in communication devices such as mobile phones, wireless infrastructure equipment, satellite communication equipment, cable TV equipment, and the like.

A control signal Ssg1 (first control signal) is input via the terminal PVc1, and a control signal Ssg2 (second control signal) is input via the terminal PVc2. The transmission line TL1 (first transmission line) has one end which is connected to the terminal Ptx (first terminal). The through-transistor T11 (first transistor) has one end which is connected to the other end of the transmission line TL1. The other end of through-transistor T11 is connected to the terminal Pant (second terminal). A gate (control terminal) of through-transistor T11 is connected to terminal PVc1 at which the control signal Ssg1 (first control signal) is input. The through-transistor T12 (second transistor) has one end which is connected to the terminal Pant. The transmission line TL2 (second transmission line) has one end which is connected to the other end of the through-transistor T12. The other end of transmission line TL2 is connected to the terminal Prx (third terminal). A gate (control terminal) of through-transistor T12 is connected to terminal PVc2 at which the control signal Ssg2 (second control signal) is input.

The shunt transistor S11 (third transistor) includes one end which is connected to the terminal Ptx, and the other end is connected to a low-potential-side power supply voltage (ground potential) Vss. A gate (control terminal) of the shunt transistor S11 is connected to terminal PVc2 at which the control signal Ssg2 is input. The shunt transistor S12 (fourth transistor) has one end which is connected to the other end of the transmission line TL2 (the end of transmission line TL2 not connected to through-transistor T12). The other end of shunt transistor S12 is connected to the low-potential-side power supply voltage (ground potential) Vss. A gate (control terminal) of shunt transistor S12 is connected to terminal PVc1 at which the control signal Ssg1 is input.

When the control signal Ssg1 is in an enable state (for example, High level) and the control signal Ssg2 is in a disable state (for example, Low level), the high frequency switching circuit 90 outputs a first high frequency signal to the terminal Pant, which is an antenna terminal, input at the terminal Ptx, which is a transmitting terminal.

When the control signal Ssg1 is in a disable state (for example, Low level) and the control signal Ssg2 is in an enable state (for example, High level), the high frequency switching circuit 90 outputs a second high frequency signal to the terminal Prx, which is a receiving terminal, received at the terminal Pant (antenna terminal). The first high frequency signal and the second high frequency signal, which have the same frequency, are used for the SPDT switch.

Outside of the high frequency switching circuit 90, a terminating impedance Zs1 is provided (on the terminal Ptx side) between the terminal Ptx and the low-potential-side power supply voltage (ground potential) Vss, a terminating impedance Zs3 is provided (on the terminal Pant side) between the terminal Pant and the low-potential-side power supply voltage (ground potential) Vss, and a terminating impedance Zs2 is provided (on the terminal Prx side) between the terminal Prx and the low-potential-side power supply voltage (ground potential) Vss.

Here, the terminating impedance is an impedance which is set according to a frequency of a high frequency signal with which the high frequency switching circuit 90 operates. For example, the terminating impedance is set to 50Ω or to a value within a range of 25Ω to 75Ω.

A silicon on insulator (SOI) type N channel metal oxide semiconductor field effect transistor (MOSFET) is used for the shunt transistor S11, the shunt transistor S12, the through-transistor T11, and the through-transistor T12. Microstrip lines, coplanar strip lines or the like are used for the transmission line TL1 and the transmission line TL2.

The transmission line TL1 is set to λ/4 in length, where λ is the corresponding wavelength for the frequency of the first and second high frequency signals, which have the same frequency. The transmission line TL1 is set in such a manner that the characteristic impedance thereof has the same value as that of the terminating impedance Zs1. The transmission line TL2 is set to λ/4 in length, where λ is corresponding wavelength of the first and second high frequency signals. The transmission line TL2 is set in such a manner that the characteristic impedance thereof has the same value as that of the terminating impedance Zs2. Here, the characteristic impedance is the impedance of the transmission line at the frequency of the high frequency signal at which the high frequency switching circuit 90 operates.

As illustrated in FIG. 2, a high frequency switching circuit 100 of a comparison example includes a shunt transistor S11, the shunt transistor S12, the through-transistor T11, the through-transistor T12, the terminal Pant, the terminal Prx, the terminal Ptx, the terminal PVc1, and the terminal PVc2.

In the high frequency switching circuit 100 of the comparison example, the transmission line TL1 and the transmission line TL2 of the high frequency switching circuit 90 according to the first embodiment are omitted.

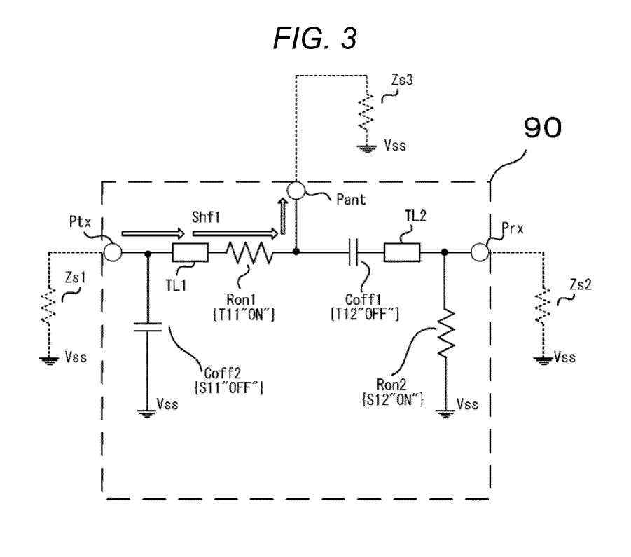

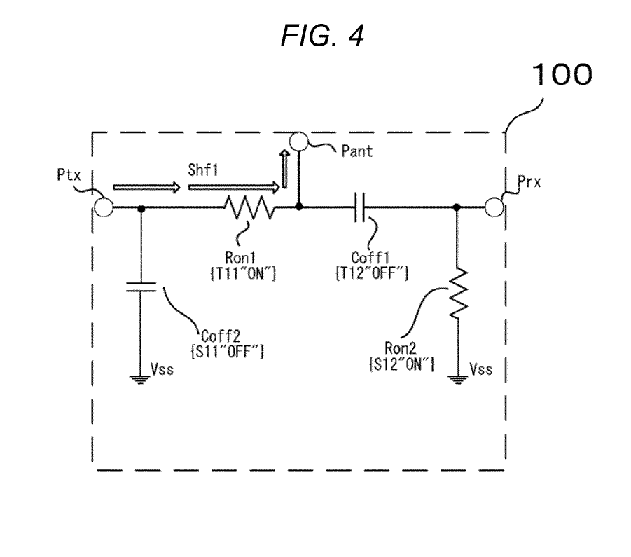

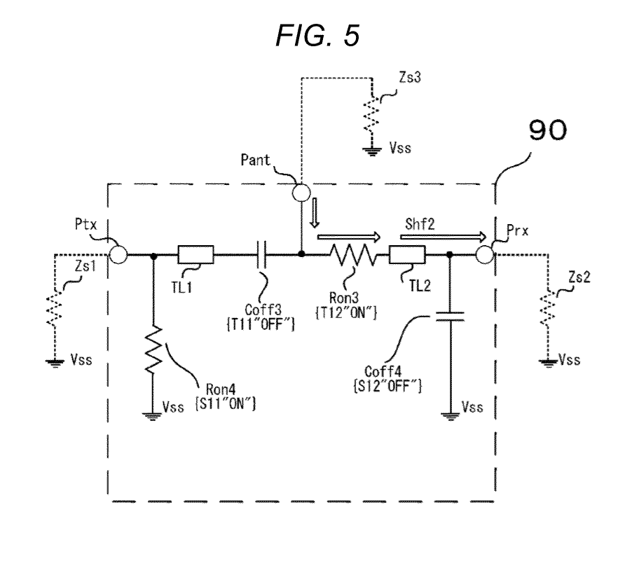

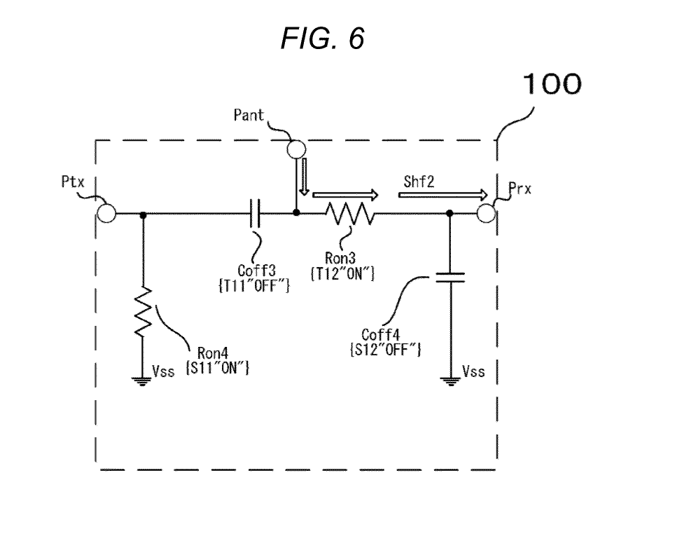

Next, the operation of the high frequency switching circuits 90 and 100 will be described with reference to FIGS. 3 to 6. FIG. 3 is an equivalent circuit diagram of the high frequency switching circuit 90 when the first high frequency signal is output to the antenna terminal Pant from the transmitting terminal Ptx. FIG. 4 is an equivalent circuit diagram of the high frequency switching circuit 100 of the comparison example, when the first high frequency signal is output to the antenna terminal Pant via the transmitting terminal Ptx. FIG. 5 is an equivalent circuit diagram of the high frequency switching circuit 90, when the second high frequency signal from the antenna terminal Pant is output to a receiving terminal Prx. FIG. 6 is an equivalent circuit diagram of the high frequency switching circuit 100 of the comparison example, when the second high frequency signal from the antenna terminal Pant is output to a receiving terminal Prx.

As illustrated in FIG. 3, when the high frequency switching circuit 90 is in a state where the control signal Ssg1 is in an enable state and the control signal Ssg2 is in a disable state, a high frequency signal Shf1 (first high frequency signal) is transmitted from the terminal Ptx to the terminal Pant side. In this state, the through-transistor T11 turns on (becomes conducting), and is thereby being represented in FIG. 3 by an on-resistance Ron1. The shunt transistor S12 also turns on, and thereby is being represented by an on-resistance Ron2 in FIG. 3. The through-transistor T12 turns off (becomes non-conducting), and thereby is being represented by an off-capacitance Coff1 in FIG. 3. The shunt transistor S11 also turns off, and thereby is being represented by an off-capacitance Coff2 in FIG. 3.

Here, when viewing a load side, an impedance Z is represented by the following Formula (1).

Z=Zs×({Zr+(jZs×Tan(βI))}/{Z0+(jZr×Tan(βI))}) Formula (1)

Here, Zs is a terminating impedance, Zr is a load impedance, Z0 is an initial impedance, and I is a length of a transmission line (line length from the terminal Ptx to the through-transistor T11, or line length from the through-transistor T12 to the terminal Prx). β is 2π/λ (here, λ is the wavelength of the first and second high frequency signals).

In the first embodiment, the characteristic impedance of the transmission line TL1 and the terminating impedance Zs1 are set to the same value on the path from the terminal Ptx to the terminal Pant. Thus, by Formula (1), the impedance Z becomes the load impedance Zr, and the characteristic impedance of the transmission line is not dependent on the line length. For this reason, an amount of the high frequency signal Shf1 which is transmitted from the terminal Ptx to the terminal Pant side is not affected by the disposition of the transmission line TL1, thus the high frequency signal Shf1 maintains a satisfactory value and is not degraded.

Meanwhile, the path from the terminal Pant to the terminal Prx is connected to the low-potential-side power supply voltage (ground potential) Vss via the shunt transistor S12. Thus, the load impedance Zr is represented by approximately zero Ω (Zr≈0Ω). If Zr=0 is inserted into Formula (1), the impedance Z is represented by the following Formula (2).

Z≈(jZs×Tan(βI)) Formula (2)

In the high frequency signal Shf1 (first high frequency signal) and a high frequency signal Shf2 (second high frequency signal), which have the same frequency, the transmission line TL2 is set to (λ/4), and thus, if I=(λ/4) is inserted into Formula (2), the impedance Z becomes Z≈∞ (infinity).

Thus, it is possible to remarkably reduce the leakage of the high frequency signal from the terminal Pant to the terminal Prx. For this reason, it is possible to remarkably reduce insertion loss in the high frequency switching circuit 90.

As illustrated in FIG. 4, for the high frequency switching circuit 100 of the comparison example in a state where the control signal Ssg1 is in an enable state and the control signal Ssg2 is in a disable state, the high frequency signal Shf1 (first high frequency signal) is transmitted from the terminal Ptx to the terminal Pant side, and the through-transistor T11, the through-transistor T12, the shunt transistor S11, and the shunt transistor S12 are represented by the same manner as in FIG. 3.

In the high frequency switching circuit 100 of the comparison example, the transmission line TL2 is not provided between the through-transistor T12 and the terminal Prx, and thus, a portion of the high frequency signal Shf1 (first high frequency signal) leaks to the terminal Prx side via the off-capacitance Coff1, which is connected in series to the terminal Prx. Thus, the insertion loss is greater than for the first embodiment.

As illustrated in FIG. 5, when the high frequency switching circuit 90 according to the first embodiment is in a state where the control signal Ssg1 is in a disable state and the control signal Ssg2 is in an enable state, the high frequency signal Shf2 (second high frequency signal) is transmitted from the terminal Pant to the terminal Prx side. In this state, the through-transistor T12 turns on, and thereby is being represented by an on-resistance Ron3 in FIG. 5. The shunt transistor S11 also turns on, and thereby is being represented by an on-resistance Ron4. Additionally, the through-transistor T11 turns off, and thereby is being represented by an off-capacitance Coff3, and the shunt transistor S12 turns off, and thereby is being represented by an off-capacitance Coff4.

Here, when viewing a load side, an impedance Z is represented by Formula (1). In the first embodiment, the characteristic impedance of the transmission line TL2 and the terminating impedance Zs2 are set to the same value on a path from the terminal Pant to the terminal Prx. Thus, by Formula (1), the impedance Z becomes the load impedance Zr, and the characteristic impedance of the transmission line is not dependent on the line length. For this reason, an amount of the high frequency signal Shf2, which is transmitted from the terminal Pant to the terminal Prx side, is not affected by a disposition of the transmission line TL2, thus the high frequency signal Shf2 maintains a satisfactory value and is not degraded.

Meanwhile, the path from the terminal Pant to the terminal Ptx is connected to the low-potential-side power supply voltage (ground potential) Vss via the shunt transistor S11. Thus, the load impedance Zr is represented by approximately zero Ω (Zr≈0Ω).

In the high frequency signal Shf2 (second high frequency signal) and the high frequency signal Shf1 (first high frequency signal), which have the same frequency, the transmission line TL1 is set to (λ/4), and thus, if I=(λ/4) is inserted into Formula (2), the impedance Z becomes Z≈∞ (infinity).

Thus, it is possible to remarkably reduce the leakage of the high frequency signal from the terminal Pant to the terminal Ptx. For this reason, it is possible to remarkably reduce an insertion loss, in the high frequency switching circuit 90.

As illustrated in FIG. 6, in the high frequency switching circuit 100 of the comparison example, the transmission line TL1 is not provided between the through-transistor T11 and the terminal Ptx, and thus, a portion of the high frequency signal Shf2 (second high frequency signal) leaks into the terminal Ptx side via the off-capacitance Coff3 which is connected in series to the terminal Ptx. Thus, the insertion loss is increased, as compared with the first embodiment.

When the transmission line TL1 and the transmission line TL2 are imperfectly set to (λ/4) in length according to the frequencies of the first and second high frequency signals, it has been found that even with variation of approximately 30% from the intended (λ/4) length value, the leakage of the high frequency signal is still remarkably reduced as compared to the comparison example. That is, an actual line length of the first or second transmission line may vary within 30% of a nominal value set as an integer multiple of (λ/4) according to the first and second high frequency signals and still provide reduce signal leakage as compared to the comparison example.

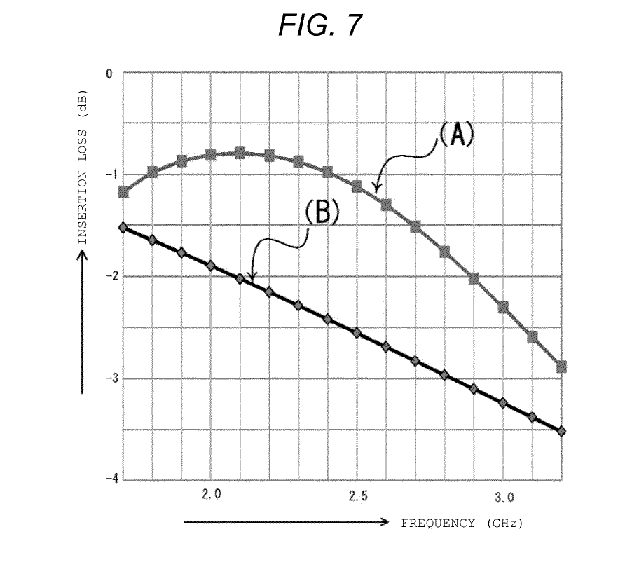

Next, characteristics of the high frequency switching circuit will be described with reference to FIG. 7. FIG. 7 is a characteristic diagram of the high frequency switching circuit depicting signal frequency (GHz) versus insertion loss (dB). Solid line (A) of FIG. 7 represents the first embodiment and solid line (B) of FIG. 7 represents the comparison example. Here, FIG. 7 is a diagram illustrating a relationship between a frequency and a insertion loss, when the high frequency signal is transmitted from the terminal Ptx to the terminal Pant side.

As illustrated in FIG. 7, the insertion loss of the high frequency switching circuit 90 (solid line (A)) is reduced as compared to the high frequency switching circuit 100 (solid line (B)). Specifically, at 2 GHz, which is an operating frequency for the high frequency signal Shf1 (first high frequency signal), the insertion loss is reduced by 1.1 dB. At 1.7 GHz, the insertion loss is reduced by 0.4 dB. At 2.3 GHz, the insertion loss is reduced by 1.4 dB.

Here, while not being specifically illustrated, it has been confirmed that the insertion loss is remarkably reduced, compared with the comparison example, even when the high frequency signal is transmitted from the terminal Pant to the terminal Prx side.

As described above, in the high frequency switching circuit according to the first embodiment, the shunt transistor S11, the shunt transistor S12, the through-transistor T11, the through-transistor T12, the transmission line TL1, the transmission line TL2, the terminal Pant, the terminal Prx, the terminal Ptx, the terminal PVc1, and the terminal PVc2 are provided. The transmission line TL1 is set to (λ/4) in length corresponding to the frequencies of the first and second high frequency signals. The characteristic impedance is set so as to be the same value as that of the terminating impedance Zs1. The transmission line TL2 is set to (λ/4) in length corresponding to the frequencies of the first and second high frequency signals. The characteristic impedance is set so as to be the same value as that of the terminating impedance Zs2.

For this reason, it is possible to remarkably reduce the leakage of the high frequency signal of the high frequency switching circuit, and to remarkably reduce the insertion loss.

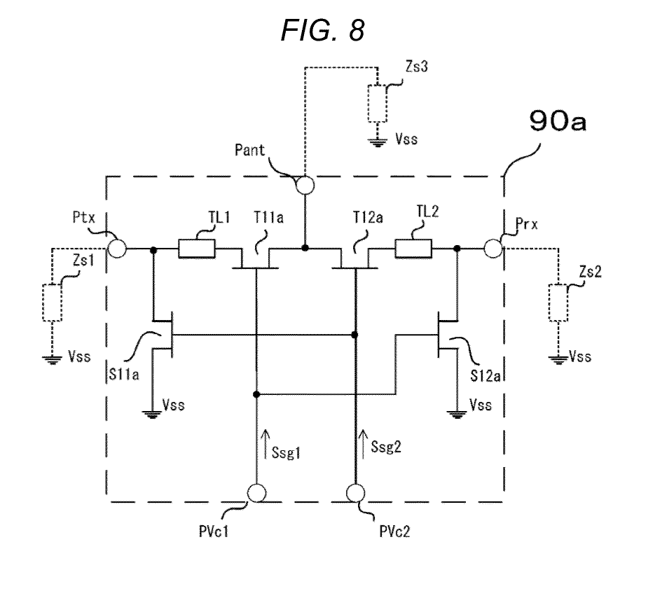

In addition, in the first embodiment, an SOI type MOSFET is used for the through-transistors and the shunt transistors, but the present embodiment is not necessarily limited to this. For example, in the same manner as in a high frequency switching circuit 90a of a first modification example illustrated in FIG. 8, a pseudomorphic high electron mobility transistor (pHEMT or pseudomorphic HEMT) using materials such as GaAs, InP, and GaN, or the like may be used for a through-transistor T11a, a through-transistor T12a, a shunt transistor S11a, and a shunt transistor S12a. The pseudomorphic HEMT is a field effect transistor in which two-dimensional electron gas (2DEG) with high mobility, which is induced in a semiconductor hetero-junction, is used as a channel, and which is changed to other material that para-lattice-adjusts the material configuring the channel. For example, the pseudomorphic HEMT may have a higher frequency and lower noise than an SOI type MOSFET or an HEMT.

In addition, in the first embodiment, the transmission line TL1 and the transmission line TL2 are set to (λ/4) in length according to the frequencies of the first and second high frequency signals, but the present disclosure is not limited to this. The line lengths of the transmission line TL1 and the transmission line TL2 may be set to integer multiples of (λ/4). When the line lengths are set to equal to or more than two times (λ/4), the leakage of the high frequency signal in the high frequency switching circuit is slightly increases and performance is degraded, compared to when the line lengths are set to (λ/4). In addition, if the line lengths are set to an integer multiple, the desired effect may still be obtained even with some error in the actual line length.

### Second Embodiment

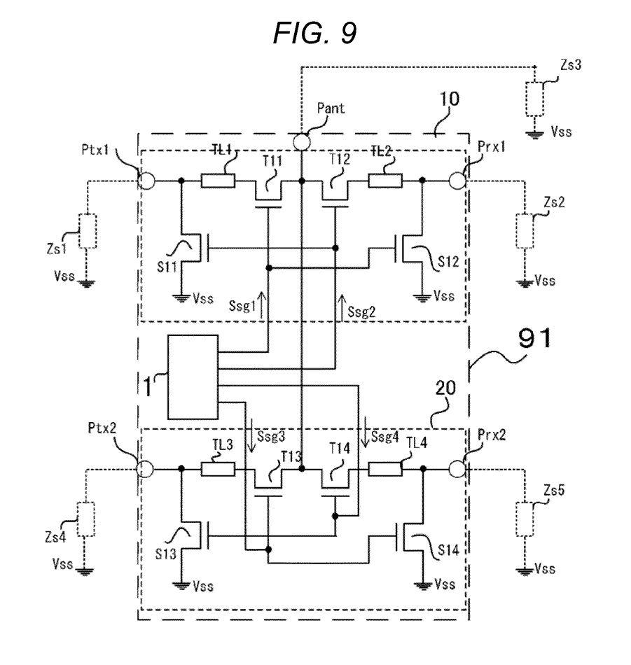

Next, a high frequency switching circuit according to a second embodiment will be described. FIG. 9 is a circuit diagram illustrating a high frequency switching circuit 91. In the second embodiment, a control unit 1 controls a plurality of SPDT switches (e.g., element 10 and element 20) each having an inserted transmission line.

Hereinafter, where the same symbols or reference numerals are used to denote the same configuration portions as those of the first embodiment, description thereof will generally be omitted, and the portions different from those will be described.

As illustrated in FIG. 9, a high frequency switching circuit 91 includes a control unit 1, an SPDT switch 10, an SPDT switch 20, and terminal Pant. The SPDT switch 10 includes the shunt transistor S11, the shunt transistor S12, the through-transistor T11, the through-transistor T12, the transmission line TL1, the transmission line TL2, a terminal Prx1, and a terminal Ptx1. The SPDT switch 20 includes a shunt transistor S13, a shunt transistor S14, a through-transistor T13, a through-transistor T14, a transmission line TL3, a transmission line TL4, a terminal Prx2, and a terminal Ptx2.

The high frequency switching circuit 91 can be used for a mobile phone, wireless infrastructure equipment, satellite communication equipment, cable TV equipment or the like.

The control unit 1 generates control signals Ssg1 to Ssg4. The control signal Ssg1 and the control signal Ssg2 are input to the SPDT switch 10. The SPDT switch 10 operates based on the control signal Ssg1 and the control signal Ssg2. The control signal Ssg3 and the control signal Ssg4 are input to the SPDT switch 20. The SPDT switch 20 operates based on the control signal Ssg3 and the control signal Ssg4.

The transmission line TL3 includes one end which is connected to the terminal Ptx2. The through-transistor T13 includes one end which is connected to the other end of the transmission line TL3. The other end of through-transistor T13 is connected to the terminal Pant. Agate (control terminal) of through-transistor T13 is connected to control unit 1 from which the control signal Ssg3 is input. The through-transistor T14 includes one end which is connected to the terminal Pant. A gate (control terminal) through-transistor T14 is connected to control unit 1 from which the control signal Ssg4 is input. The transmission line TL4 includes one end which is connected to the other end of the through-transistor T14. The other end of the transmission line TL4 is connected to the terminal Prx2.

The shunt transistor S13 includes one end which is connected to the terminal Ptx2 and the other end of shunt transistor S13 is connected to the low-potential-side power supply voltage (ground potential) Vss. A gate (control terminal) of shunt transistor S13 is connected to control unit 1 from which the control signal Ssg4 is input. The shunt transistor S14 includes one end which is connected to the other end of the transmission line TL4, and the other end of shunt transistor S14 is connected to the low-potential-side power supply voltage (ground potential) Vss. A gate (control terminal) of shunt transistor S14 is connected to control unit 1 from which the control signal Ssg3 is input.

When the control signal Ssg3 is in a enable state (for example, High level) and the control signal Ssg4 is in an disable state (for example, Low level), the SPDT switch 20 outputs a third high frequency signal to the terminal Pant, which is an antenna terminal, from the terminal Ptx2, which is a transmitting terminal.

When the control signal Ssg3 is in a disable state (for example, Low level) and the control signal Ssg4 is in an enable state (for example, High level), the SPDT switch 20 outputs a fourth high frequency signal to the terminal Prx2, which is a receiving terminal, from the terminal Pant, which is an antenna terminal. The SPDT switch 20 uses the third high frequency signal and the fourth high frequency signal which have the same frequency.

The high frequency signal used for the SPDT switch 10 and the high frequency signal used for the SPDT switch 20 may be the same frequency, or may be different from each other in frequency. If the frequencies of the two signals are different from each other, it is preferable that the selected frequencies be within a band in which insertion loss is small when compared with the comparison example as illustrated in FIG. 7.

Outside the high frequency switching circuit 91, the terminating impedance Zs1 is provided (on the terminal Ptx1 side) between the terminal Ptx1 and the low-potential-side power supply voltage (ground potential) Vss. The terminating impedance Zs3 is provided (on the terminal Pant side) between the terminal Pant and the low-potential-side power supply voltage (ground potential) Vss. The terminating impedance Zs2 is provided (on the terminal Prx1 side) between the terminal Prx1 and the low-potential-side power supply voltage (ground potential) Vss. A terminating impedance Zs4 is provided (on the terminal Ptx2 side) between the terminal Ptx2 and the low-potential-side power supply voltage (ground potential) Vss. A terminating impedance Zs5 is provided (on the terminal Prx2 side) between the terminal Prx2 and the low-potential-side power supply voltage (ground potential) Vss.

The transmission line TL3 is set to λ/4 (here, λ is wavelength) in length according to the frequencies of the third and fourth high frequency signals. The transmission line TL3 is set in such a manner that the characteristic impedance thereof has the same value as that of the terminating impedance Zs4. The transmission line TL4 is set to λ/4 (here, λ is wavelength) in length according to the frequencies of the third and fourth high frequency signals. The transmission line TL4 is set in such a manner that the characteristic impedance thereof has the same value as that of the terminating impedance Zs5.

In the high frequency switching circuit 91 according to the second embodiment, in a state where the control signal Ssg1 is in an enable state and the control signals Ssg2 to Ssg4 are in a disable state, the high frequency signal Shf1 (first high frequency signal) is transmitted from the terminal Ptx1 to the terminal Pant side. At this time, the through-transistor T11 and the shunt transistor S12 turn on, and the through-transistors T12 to T14, the shunt transistor S11, the shunt transistor S13, and the shunt transistor S14 turn off.

In a state where the control signal Ssg2 is in an enable state, and the control signal Ssg1, the control signal Ssg3, and the control signal Ssg4 are in a disable state, the high frequency signal Shf2 (second high frequency signal) is transmitted from the terminal Pant to the terminal Prx1 side. At this time, the through-transistor T12 and the shunt transistor S11 turn on, and the through-transistor T11, the through-transistor T13, the through-transistor T14, and the shunt transistors S12 to S14 turn off.

In a state where the control signal Ssg3 is in an enable state, and the control signal Ssg1, the control signal Ssg2, and the control signal Ssg4 are in a disable state, the third high frequency signal is transmitted from the terminal Ptx2 to the terminal Pant side. At this time, the through-transistor T13 and the shunt transistor S14 turn on, and the through-transistor T11, the through-transistor T12, the through-transistor T14, and the shunt transistors S11 to S13 turn off.

In a state where the control signal Ssg4 is in an enable state, and the control signals Ssg1 to Ssg3 are in a disable state, the fourth high frequency signal is transmitted from the terminal Pant to the terminal Prx2 side. At this time, the through-transistor T14 and the shunt transistor S13 turn on, and the through-transistors T11 to T13, the shunt transistor S11, the shunt transistor S12, and the shunt transistor S14 turn off.

In the a similar manner as in the first embodiment, the SPDT switch 10 and the SPDT switch 20 reduce the leakage of the high frequency signal and remarkably reduce the insertion loss.

As described above, in the high frequency switching circuit according to the second embodiment, the control unit 1, the SPDT switch 10, and the SPDT switch 20 are provided. The SPDT switch 10 includes the shunt transistor S11, the shunt transistor S12, the through-transistor T11, the through-transistor T12, the transmission line TL1, the transmission line TL2, the terminal Prx1, and the terminal Ptx1. The SPDT switch 20 includes the shunt transistor S13, the shunt transistor S14, the through-transistor T13, the through-transistor T14, the transmission line TL3, the transmission line TL4, the terminal Prx2, and the terminal Ptx2. The transmission line TL1 is set to λ/4 in length according to the frequencies of the first and second high frequency signals, and is set in such a manner that the characteristic impedance thereof has the same value as that of the terminating impedance Zs1. The transmission line TL2 is set to λ/4 in length according to the frequencies of the first and second high frequency signals, and is set in such a manner that the characteristic impedance thereof has the same value as that of the terminating impedance Zs2. The transmission line TL3 is set to λ/4 in length according to the frequencies of the third and fourth high frequency signals, and is set in such a manner that the characteristic impedance thereof has the same value as that of the terminating impedance Zs4. The transmission line TL4 is set to λ/4 in length according to the frequencies of the third and fourth high frequency signals, and is set in such a manner that the characteristic impedance thereof has the same value as that of the terminating impedance Zs5.

For this reason, it is possible to reduce the leakage of the high frequency signal of the high frequency switching circuit, and to remarkably reduce the insertion loss.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A high frequency switching circuit for high frequency signals including a first high frequency signal that is input through a first terminal and a second high frequency signal that is input through a second terminal, comprising:
a first transmission line connecting a first end of a first transistor to the first terminal, the first transmission line having a line length that is an integer multiple of a quarter of a wavelength of the first high frequency signal;
a second end of the first transistor connected to the second terminal;
a control electrode of the first transistor connected to a first control input terminal at which a first control signal is receivable;
a second transmission line connecting a first end of a second transistor and a third terminal, the second transmission line having a line length that is an integer multiple of a quarter of a wavelength of the second high frequency signal;
a second end of the second transistor connected to the second terminal; and
a control electrode of the second transistor connected to a second control input terminal at which a second control signal is receivable.

2. The high frequency switching circuit according to claim 1, further comprising:
a third transistor connected between the first terminal and ground potential, a control electrode of the third transistor connected the second control input terminal; and
a fourth transistor connected between the third terminal and ground potential, a control electrode connected to the first control input terminal.

3. The high frequency switching circuit according to claim 2, wherein the first through fourth transistors are silicon-on-insulator (SOI) type MOSFETs.

4. The high frequency switching circuit according to claim 2, wherein the first through fourth transistors are pseudomorphic high electron mobility transistors (pHEMT).

5. The high frequency switching circuit according to claim 1, wherein
a characteristic impedance of the first transmission line is equal to a first terminating impedance that is between the first terminal and ground potential, and
a characteristic impedance of the second transmission line is equal to a second terminating impedance that is between the third terminal and ground potential.

6. The high frequency switching circuit according to claim 1, wherein the first and second transistors are metal-oxide-semiconductor field effect transistors (MOSFETs).

7. The high frequency switching circuit according to claim 6, wherein the first and second transistors are silicon-on-insulator (SOI) type MOSFETs.

8. The high frequency switching circuit according to claim 1, wherein the first and second transistors are pseudomorphic high electron mobility transistors (pHEMT).

9. The high frequency switching circuit according to claim 1, wherein
the high frequency switching circuit is a single pole, double throw (SPDT) switch,
the first high frequency signal and the second high frequency signal have a same frequency,
the first terminal is a transmitting terminal,
the second terminal is an antenna terminal, and
the third terminal is a receiving terminal.

10. A communications device including the high frequency switching circuit according to claim 1.

11. The high frequency switching circuit according to claim 1, wherein the high frequency signals include a third high frequency signal that is input through a fourth terminal and, and further comprising:
a third transmission line connecting a first end of a third transistor to the fourth terminal, the third transmission line having a line length that is an integer multiple of a quarter of a wavelength of the third high frequency signal;
a second end of the third transistor connected to the second terminal;
a control electrode of the third transistor connected to a third control input terminal at which a third control signal is receivable;
a fourth transmission line connecting a first end of a fourth transistor and a fifth terminal, the fourth transmission line having a line length that is an integer multiple of a quarter of a wavelength of a fourth high frequency signal that is input at the second terminal;
a second end of the fourth transistor connected to the second terminal; and
a control electrode of the fourth transistor connected to a fourth control input terminal at which a fourth control signal is receivable.

12. The high frequency switching circuit according to claim 11, further comprising a control unit configured to supply the first through fourth control signals to the respective first through fourth control input terminals.

13. A communications device, comprising:
a first transmission line connecting a first end of a first transistor to a first terminal, the first transmission line having a line length that is an integer multiple of a quarter of a wavelength of a first signal that is input to the first terminal;
a second end of the first transistor connected to an antenna terminal;
a control electrode of the first transistor connected to a first control input terminal at which a first control signal is receivable;
a second transmission line connecting a first end of a second transistor and a second terminal, the second transmission line having a line length that is an integer multiple of a quarter of a wavelength of a second signal that is input to the antenna terminal;
a second end of the second transistor connected to the antenna terminal;
a control electrode of the second transistor connected to a second control input terminal at which a second control signal is receivable;
a third transistor connected between the transmitter terminal and ground potential, a control electrode of the third transistor connected the second control input terminal; and
a fourth transistor connected between the second terminal and ground potential, a control electrode of the fourth transistor connected to the first control input terminal.

14. The communications device according to claim 13, wherein the first through fourth transistors are silicon-on-insulator (SOI) type metal-oxide-semiconductor field effect transistors (MOSFETs).

15. The communications device according to claim 13, wherein the first through fourth transistors are pseudomorphic high electron mobility transistors (pHEMT).

16. The communications device according to claim 13, wherein
a characteristic impedance of the first transmission line is equal to a first terminating impedance that is between the first terminal and ground potential, and
a characteristic impedance of the second transmission line is equal to a second terminating impedance that is between the second terminal and ground potential.

17. The communications device according to claim 13, wherein the first and second transmission lines are microstrip lines.

18. The communications device according to claim 13, wherein the first and second signals have the same wavelength.

19. A high frequency switching circuit for high frequency signals including a first high frequency signal that is input through a first terminal and a second high frequency signal that is input through a second terminal, comprising:
a first transmission line connecting a first end of a first transistor to the first terminal, the first transmission line having a line length that is within 30% of an integer multiple of a quarter of a wavelength of the first high frequency signal;
a second end of the first transistor connected to the second terminal;
a control electrode of the first transistor connected to a first control input terminal at which a first control signal is receivable;
a second transmission line connecting a first end of a second transistor and a third terminal, the second transmission line having a line length that is within 30% of an integer multiple of a quarter of a wavelength of the second high frequency signal;
a second end of the second transistor connected to the second terminal; and
a control electrode of the second transistor connected to a second control input terminal at which a second control signal is receivable.

20. The high frequency switching circuit according to claim 19, further comprising:
a third transistor connected between the first terminal and ground potential, a control electrode of the third transistor connected the second control input terminal; and
a fourth transistor connected between the third terminal and ground potential, a control electrode connected to the first control input terminal.
